(19) United States
(12) Patent Application Publication
(10) Pub. No.: US 2005/0184793 A1
(43) Pub. Date: Aug. 25, 2005

(54) Circuit for dynamic control of a power transistor in applications for high voltage

(75) Inventors: Antonino Torres, Catania (IT); Davide Patti, Catania (IT)

Correspondence Address: GRAYBEAL JACKSON HALEY LLP;Suite 350, 155-108th Avenue N.E., Bellevue, WA, 98004-5973, US

(73) Assignee: STMicroelectronics S.r.I.

(21) Appl. No.: 11/042,469

(22) Filed: Jan. 24, 2005

(30) Foreign Application Priority Data
Jan. 22, 2004 (EP) 04425035.5

(51) Int. Cl. H03L 5/00

(52) U.S. Cl. 327/478

(57) ABSTRACT

A circuit for dynamic control of a power transistor in applications for high voltage and of the type wherein a power transistor has a conduction terminal connected to a load and a control terminal receiving a driving signal from a driver block activated by a trigger signal received on a circuit input terminal. Advantageously, the circuit comprises a JFET component inserted between the conduction and control terminal of the power transistor and equal to a resistance with a non-linear feature. Moreover, the JFET component may be monolithically integrated in the structure of said power transistor.

### PRIORITY CLAIM

This application claims priority from European patent application No. 04425035.5, filed Jan. 22, 2004, which is incorporated herein by reference.

### TECHNICAL FIELD

The present invention relates generally to a circuit for dynamic control of a power transistor in applications for high voltage.

More specifically, the invention relates to a circuit for dynamic control of a power transistor in applications for high voltage comprising a power transistor with a conduction terminal connected to a load and a control terminal receiving a driving signal from a driver block activated by a trigger signal, received on a circuit input terminal. The invention particularly relates, but not exclusively, to a circuit for dynamic control of a power transistor of the IGBT type, in applications for high voltage, and the following description is made with reference to this field of application for convenience of illustration only.

### BACKGROUND

Microprocessor-driven control systems for electronic ignition are known. These systems, in their most general form, allow a spark to be generated on a spark plug associated with an internal-combustion engine.

In particular, a control circuit for electronic ignition, globally indicated with 1, is schematically shown in FIG. 1.

The control circuit 1 receives a trigger pulse Vin produced for example by a microprocessor (not shown in the figure) and applied to an input terminal IN connected to a driving terminal of an operated switch SW1.

The switch SW1 is inserted between a first voltage reference, particularly a supply voltage reference Vbat, and a second voltage reference, particularly a ground GND.

The switch SW1 is also connected to a primary coil winding 1A, connected in turn to said supply voltage reference Vbat and to an ignition sparking plug 1B.

At the ends of the switch SW1, driven by the trigger pulse Vin, there is a voltage value V_{SW1}.

The trigger pulse Vin determines the charging time of the primary coil winding 1A, closing the switch SW1 through which a current I_{COIL} flows, as shown in FIG. 2.

In particular, for a time t<t1, the trigger signal Vin has a low value and, consequently, the switch SW1 is open, keeping also the current value I_{COIL} low and the voltage V_{SW1} is equal to the voltage Vbat.

For t=t1, the microprocessor brings the trigger signal Vin to a high value which, closing the switch SW1, allows the current I_{COIL} to flow in the coil winding 1A.

The trigger signal Vin is kept high until a time t3. In the interval t1<t<t3, in correspondence with the high value of the trigger signal Vin, the coil current I_{COIL} increases with a slope trend until it reaches a maximum value in correspondence with a time t2 being lower than t3, remaining thus at this value until the time t3.

Therefore, the trigger signal Vin goes back to the low state and it consequently opens the switch SW1. At this time t3, the voltage V_{SW1} at the ends of the switch virtually instantaneously reaches a high value. An overvoltage thus occurs on the primary coil winding 1A which, transferring to the secondary through the coil turn ratio, generates a spark on the spark plug 1B.

An implementation of the control circuit 1 of FIG. 1, timed as described in FIG. 2, is shown in FIG. 3, wherein the switch SW1 is realized by means of a power element, particularly an insulated-gate bipolar transistor (IGBT).

The control circuit 2 for electronic ignition receives on a first input terminal IN1 the trigger pulse Vin produced by a microprocessor not shown in the figure.

It also receives, on a second input terminal IN2, a reference voltage value Vref, produced by a convenient reference voltage generator 3.

The control circuit 2 comprises a power element, particularly an IGBT transistor TR1 used as switch, comprised between the supply voltage reference Vbat and the ground GND.

The transistor TR1 has a first conduction terminal, particularly the collector terminal C, coupled to a supply voltage reference Vbat by means of the coil 1A, a second conduction terminal, particularly the emitter terminal E, coupled to the ground GND by means of a sensing resistance Rsen, as well as a control terminal, particularly a gate terminal G1 connected, by means of a driver block 4, to the first input terminal of the control circuit 2.

The driver block 4 is also connected to the supply voltage reference Vbat.

The control circuit 2 also comprises a current limiting block 5 inserted between the control terminal G1 and the emitter terminal E of the transistor TR1 and comprising an operational amplifier OP1.

In particular, the operational amplifier OP1 is a fed-back non inverting amplifier having a non inverting input terminal (+) connected to the emitter terminal E, an inverting input terminal (−) connected to the reference voltage generator 3 and an output terminal connected to the control terminal G1 of the transistor TR1.

The coil current value Icoil is then limited by means of the comparator OP11 reading the drop at the ends of the sensing resistance Rsen, being proportional to the coil current Icoil, comparing it with the reference voltage Vref and conveniently biasing the control terminal G1 of the transistor TR1, in order not to exceed a predetermined maximum current value.

In practice, in order to stabilize a fed-back configuration as the one shown in FIG. 3, a convenient dynamic compensation mechanism typically must be provided.

To this aim, it is known to use a compensation resistance Rf inserted between the collector terminal C and the control terminal G1 of the transistor TR1, as schematically shown in FIG. 4.

Actually, this solution cannot be used in the case of a circuit which must operate at high voltage, as in the case of an electronic ignition application, wherein, in order to have a spark in the secondary, it is necessary that the voltage detected at the collector terminal C, upon the transistor TR1 turn-off by means of the trigger voltage Vin, reaches values of some hundreds of volts.

In fact, in this case, the resistance Rf prevents the voltage on the collector terminal C from reaching such a high desired value, since it would trigger, before reaching this value, a new turn-on of the IGBT power transistor TR1.

Therefore, a need has arisen for a dynamic compensation circuit for a power transistor, like an IGBT transistor, having such structural and functional features as to be capable of operating at high voltage, overcoming the limits and/or drawbacks still affecting prior-art circuits.

### SUMMARY

In an embodiment of the present invention, a JFET transistor is integrated in the same power transistor structure, allowing a resistance with a non-linear feature to be integrated.

### BRIEF DESCRIPTION OF THE DRAWINGS

Features and advantages of a device according to the invention will be apparent from the following description of an embodiment thereof given by way of indicative and non-limiting example with reference to the attached drawings.

FIG. 1 shows a control circuit for an electronic ignition system, realized according to the prior art.

FIG. 2 shows the trend in time of signals within said circuit of FIG. 1, according to the prior art.

FIG. 3 shows, in greater detail, an embodiment of said control circuit of FIG. 1, according to the prior art.

FIG. 4 shows, in greater detail, an alternative embodiment of said control circuit of FIG. 1, according to the prior art.

FIG. 5 shows an integrated structure according to an embodiment of the present invention to realize a control circuit for an IGBT transistor using an integrated resistance realized in the ViPower technology.

FIG. 6 shows the trend of the electric feature of said resistance of FIG. 5 according to an embodiment of the invention.

FIG. 7 schematically shows an integrated structure effective to implement a JFET transistor being integrated in the structure of said IGBT transistor, according to an embodiment of the invention;

FIG. 8 shows the trend of a typical curve of the JFET transistor of FIG. 7, according to an embodiment of the invention.

FIG. 9 shows a control circuit for a power transistor, for example an IGBT transistor realized according to an embodiment of the invention.

FIG. 10 shows an alternative embodiment of said control circuit of FIG. 9, according to the invention.

FIGS. 11A and 11B show the trend of waveforms obtained by simulating said control circuit, according to an embodiment of the invention.

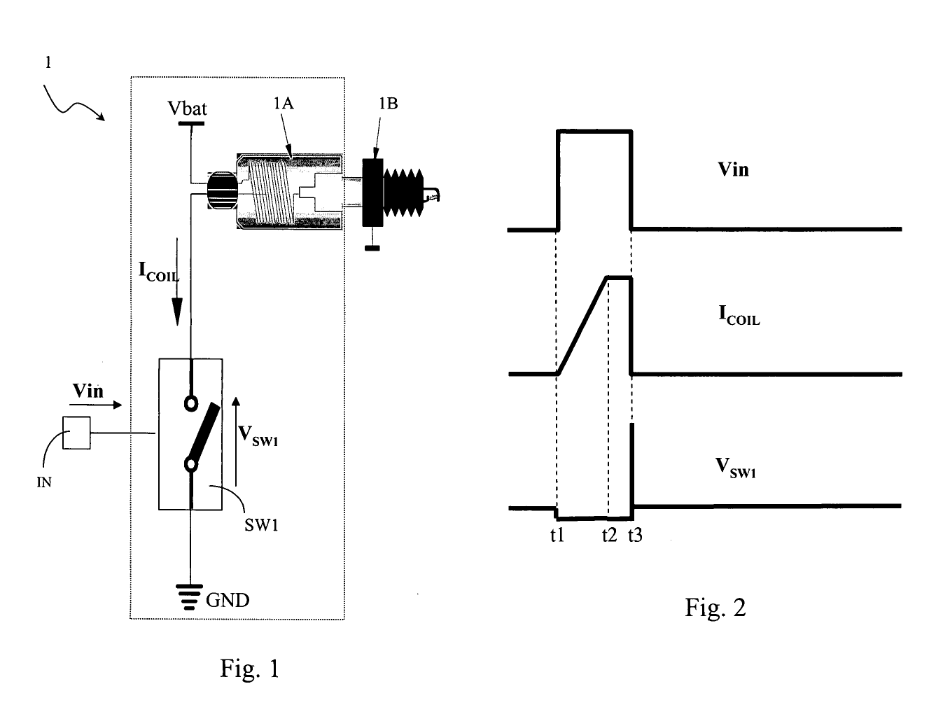

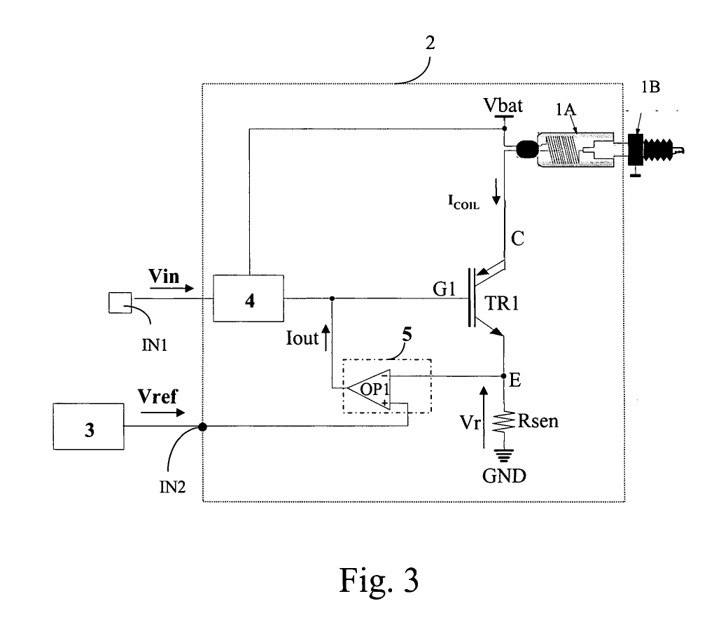

### DETAILED DESCRIPTION

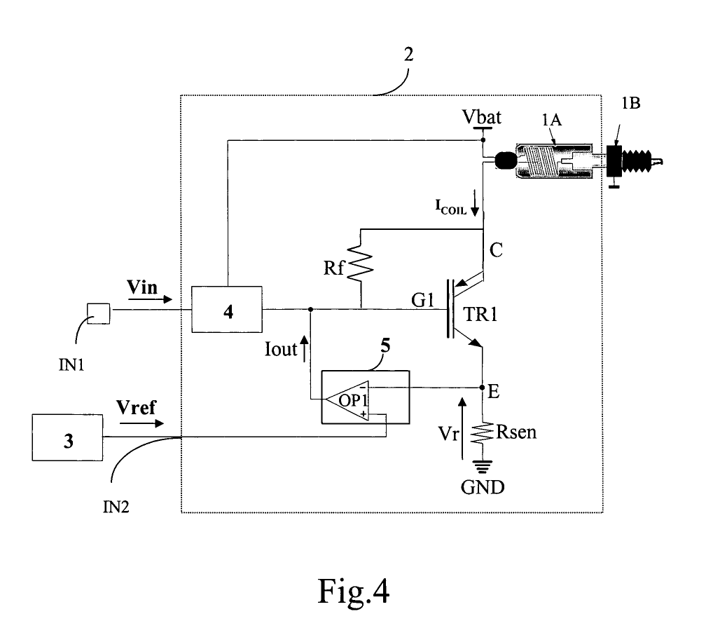

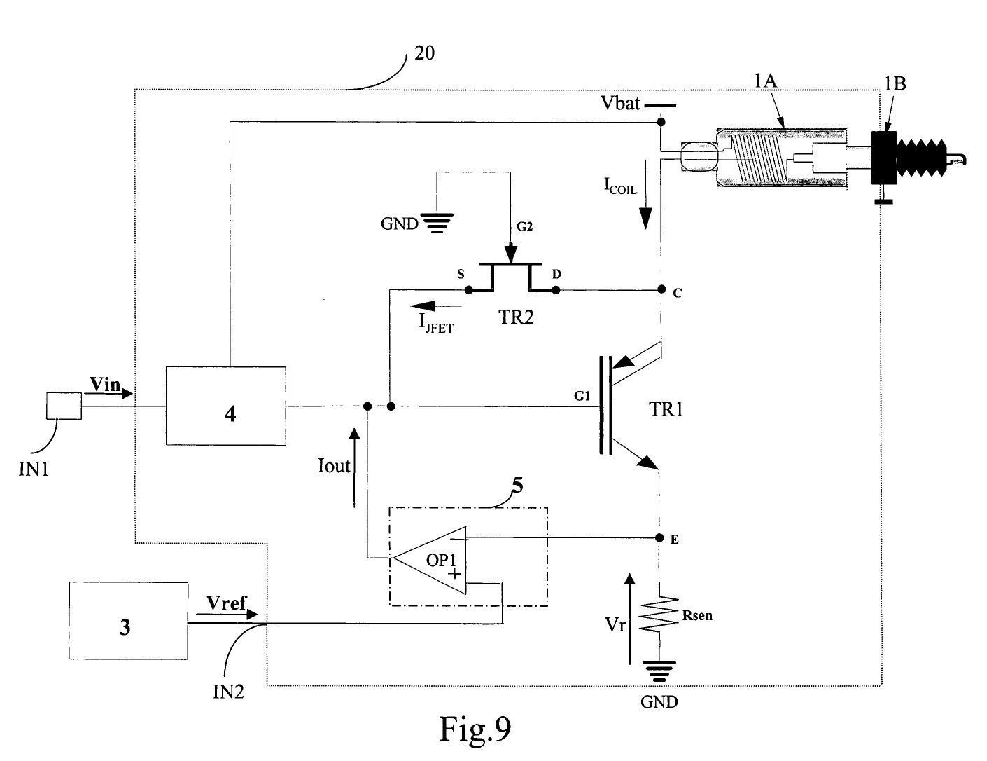

With reference to these drawings, and particularly to the example of FIG. 9, a control circuit for a power transistor, for example an IGBT transistor, which has been advantageously modified according to an embodiment of the invention with respect to the known solution of FIG. 4 and by inserting a JFET transistor TR2 in place of the resistance Rf of FIG. 4, is shown with 20.

The circuit 20 is particularly, but not exclusively, suitable for applications in the automotive field for the electronic ignition in endothermic engines.

In FIG. 9 components and signals having the same structure and operation as the ones of FIG. 4 will keep the same reference numbers and acronyms.

In particular, the JFET transistor TR2 is connected, by means of a conduction terminal D thereof, particularly a drain terminal, to a first conduction terminal, particularly a collector terminal C, of the IGBT transistor TR1.

The JFET transistor TR2 is also connected, by means of another conduction terminal S, particularly a source terminal, to the control terminal, i.e., the gate terminal G1, of said IGBT transistor TR1.

The control terminal, i.e., the gate terminal G2, of said transistor TR2 is directly connected to a voltage reference, for example a ground GND.

Advantageously, according to an embodiment of the invention, said JFET transistor TR2 is inserted in said control circuit 20, integrated in the same structure of said IGBT transistor TR1, allowing a driver for said IGBT transistor to be realized, using a low-voltage technology.

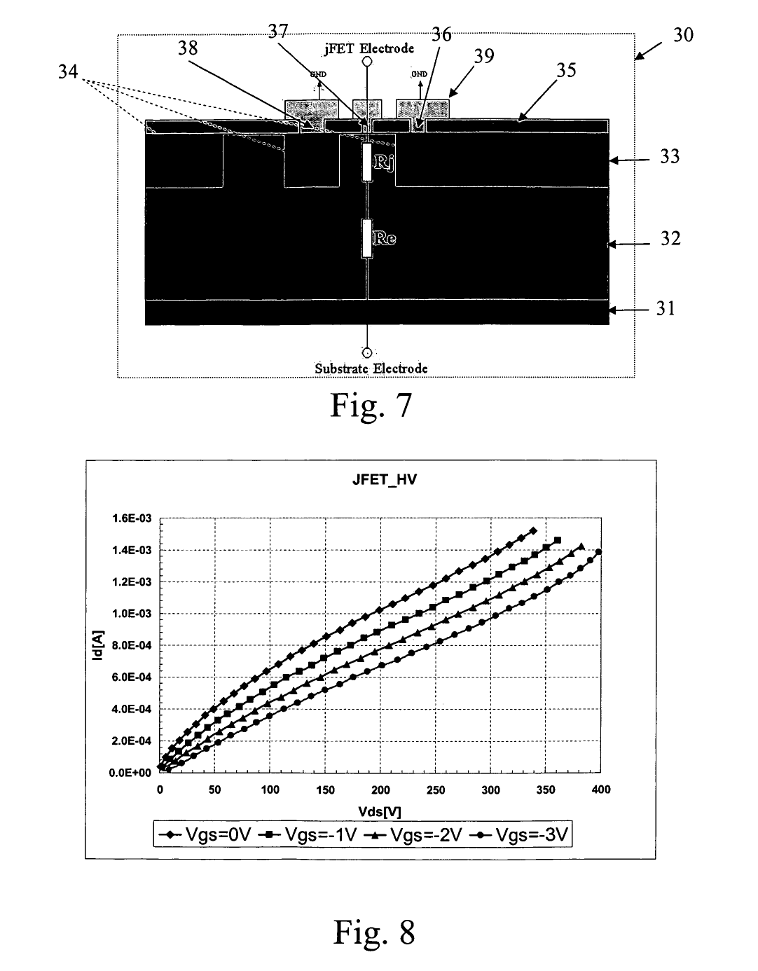

In particular, FIG. 7 schematically shows a sectional and enlarged-scale view of a structure of semiconductor-integrated electronic circuit 30 to realize in an integrated way the JFET transistor TR2 in the structure of said IGBT transistor TR11.

Said structure 30 comprises a silicon substrate 32 having a first conductivity type N and associated with a metal electrode 31, as well as a plurality of silicon wells 33, 34 having a second conductivity type P, realized above said substrate 32.

The well 33 is the body region of said JFET transistor TR2, while the well 34 is the active area of the JFET transistor.

The structure 30 is covered by an oxide layer 35 with contact openings 36, 37 and 38 in correspondence with the wells 33 and 34.

Metal layer ends 39 are overlapped to said layer 35 and in contact with said layer 32 through said opening 37, as well as with said well 33 through the opening 36 and with said well 34 through the opening 38.

FIG. 7 also shows, overlapped, the circuit equivalents of said layer 32 and of said JFET transistor TR2 represented by a resistance Re and a resistance Rj respectively.

FIG. 8 shows the typical curves of the circuit being implemented by the structure of FIG. 7.

As it can be noticed from the diagram of FIG. 8, said JFET transistor TR2 is always conducting for a gate voltage equal to zero volts and the current I_{JFET} thereof decreases, reverse-biasing the gate source junction, up to the pinch-off voltage value, equal to about −4V, for which said JFET transistor TR2 is completely inhibited.

With a low-voltage technology it is thus possible to design control circuits of IGBT transistors such as said transistor TR1 which, in order to ensure the stability of the whole system, use a JFET transistor, in particular said JFET transistor TR2 is used as feedback resistance.

When the JFET transistor TR2 is directly connected between the first conduction terminal, the collector C, and the control terminal, the gate G1 of the IGBT transistor TR1, a real feedback of the collector voltage may not occur under some conditions since the voltage between the gate G2 and the source S of the transistor TR2 is equal to the voltage between the gate G1 and the ground GND and it may extinguish the current IJFET with subsequent circuit instability.

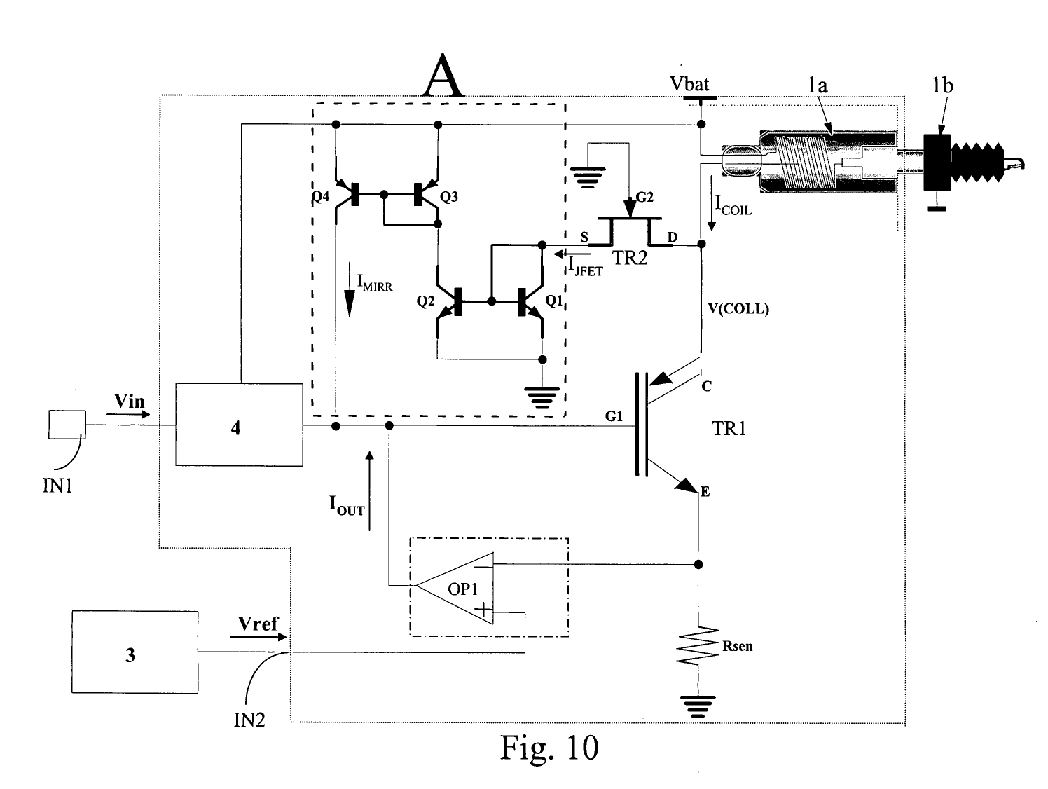

Advantageously, according to an embodiment the invention, in order to feedback the collector voltage, the circuit of FIG. 9 can be modified as in FIG. 10, wherein components and signals being already in FIG. 9 will keep the same labels as in FIG. 9.

In particular, a block A, located in the dashed-line box, has been inserted in FIG. 10, through which the source terminal S of said JFET transistor TR2 is not directly connected to the gate G1 of the IGBT transistor TR1, but to the collector terminal of a first diode-connected bipolar transistor Q1 of the NPN type, having the emitter terminal connected to the ground and being also connected through its base to the base terminal of a second bipolar transistor Q2 of the NPN type used as current mirror.

In this way the voltage between the gate terminal G2 and the source terminal S of said JFET transistor TR2, corresponding to the voltage drop between the base and the emitter of said first bipolar transistor Q1 of the NPN type with opposite sign, is always lower in absolute value than the pinch-off voltage.

Moreover, this voltage is almost constant, and thus said second JFET transistor TR2 is forced to operate on a predetermined output feature, allowing a constant resistance value to be obtained in the ohmic area.

The collector terminal of said second bipolar transistor Q2 of the NPN type is connected to the collector terminal of a third bipolar transistor Q3 of the PNP type, being connected in turn, in a current mirror configuration, to a forth bipolar transistor Q4 of the PNP type.

The pairs of transistors Q1, Q2 and Q3, Q4 are substantially two current mirrors.

The collector current I_{MIRR} outputted by said forth bipolar transistor Q4 will then be equal to said current I_{JFET} supplied by said JFET transistor TR2 (assuming that Q1, Q2, Q3, and Q4 are dimensioned for I_{MIRR}=I_{JFET}).

By connecting the collector terminal of said forth bipolar transistor Q4 to said first gate terminal G1 of said IGBT transistor TR1, a feedback occurs from the collector terminal C, which is independent from the value of the gate voltage calculated in said gate terminal G1.

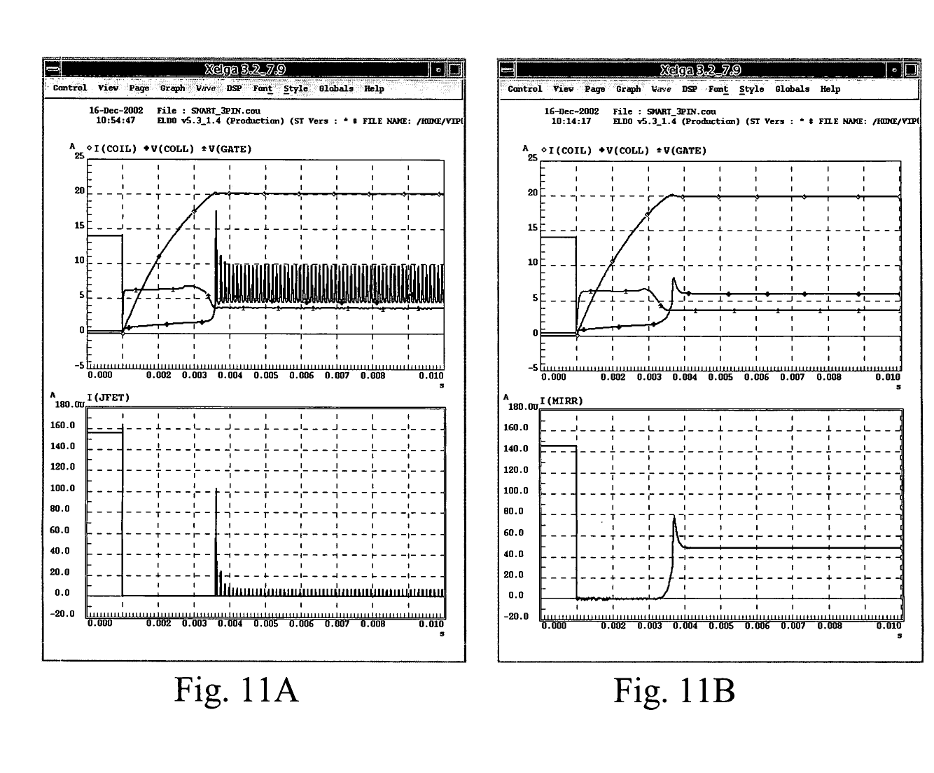

FIG. 11 a shows the results of the simulation of the circuit of FIG. 9 and FIG. 11b shows those related to the circuit of FIG. 10.

In FIG. 11a, it can be seen that, by using the JFET transistor TR2 located as the prior art resistance Rf, i.e., by directly connecting it between said collector terminal C and said gate terminal G1 of the IGBT transistor TR1, the feedback current I_{JFET} is zero when the voltage of said gate terminal G1 increases, and oscillations thus arise on the collector voltage, it being impossible to stabilize the fed-back circuit.

FIG. 11b relates to the simulation of the same circuit wherein the block A of FIG. 10 has been introduced.

In this case too, in the current limitation step, the voltage calculated on the gate terminal G1 of said IGBT transistor TR1 reaches about 4V, but said JFET transistor TR2 is not inhibited, since it always detects between the source terminal S and the gate terminal G2 a voltage being equal to the voltage calculated between the base and emitter terminals of said first bipolar transistor Q1 of the NPN type.

The current I_{MIRR}, obtained by mirroring the current I_{JFET} calculated in the source terminal S of the JFET transistor TR2, being not void, thus allows the feedback from the collector voltage required for the circuit stabilization to be obtained.

This feedback is also used to reduce the collector voltage overshoot occurring at the beginning of the current limitation step, when said IGBT transistor TR1 passes from the ohmic operation area thereof to the saturation area.

Advantages with respect to the prior art.

A remarkable advantage of the JFET structure integrated inside an IGBT transistor is that of providing, with circuits realized by using low voltage technologies, all those circuit solutions previously requiring the use of high-voltage technologies.

In fact the prior art provided, for control circuits, for the realisation of high-voltage structures being effective to directly interface with the IGBT transistor collector.

On the contrary, the proposed solution provides that the feedback from the IGBT transistor collector voltage is obtained by realizing an interface locating in the same IGBT transistor structure the high-voltage area, in order to obtain a low-voltage signal which can be operated by means of circuits which can be realized in any of the low-voltage technologies.

The proposed solution, of which a circuit embodiment can be seen in block A of FIG. 10, provides the realization of an interface being capable to modify the feedback signal of the collector voltage, coming from the JFET transistor structure, to make it suitable for driving the IGBT transistor gate terminal G1.

This circuit forces the JFET transistor to operate at a constant voltage (Vgs) calculated between the gate terminal and the source terminal, so that said transistor can be used on a predetermined output feature.

Another embodiment of a control circuit for an IGBT transistor, using the resistance Rf of FIG. 4, is obtained by using a technology called ViPower.

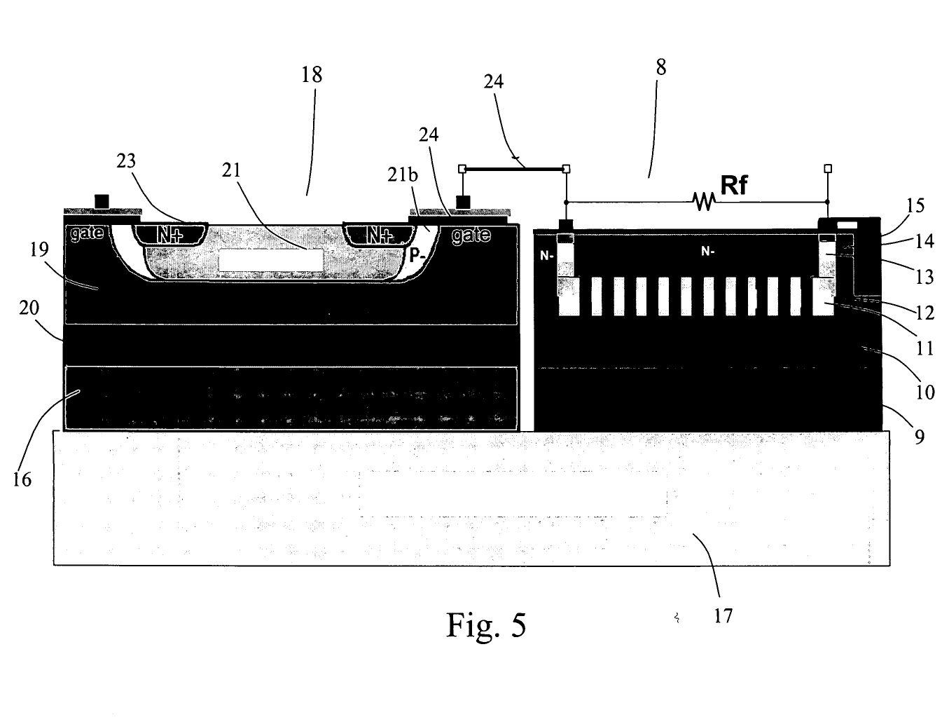

FIG. 5 shows an example of a possible exploitation of the ViPower technology to realize a control circuit for said IGBT transistor TR1, globally indicated with 18 in the figure, using said resistance Rf, globally indicated with 8 in the figure.

In particular, the integrated structure 8 is effective to implement, with the ViPower technology, a high-voltage resistance.

The resistive structure 8 is integrated on a first semiconductor epitaxial layer 10 of a first conductivity type N, slightly doped (N−), located on a semiconductor substrate 9 of said first heavily doped conductivity type (N+); the resistive structure 8 comprises a plurality of buried and parallel regions 12, of a second conductivity type P, realized in the epitaxial layer 10.

The resistive structure 8 also comprises two opposite end regions 13, always having said second heavily doped conductivity type (P+), in contact with the two buried end regions 12. At least a region 13 is laterally separated from a region 15 having a first heavily doped conductivity type (N+) by means of a portion 14 of the epitaxial layer 10.

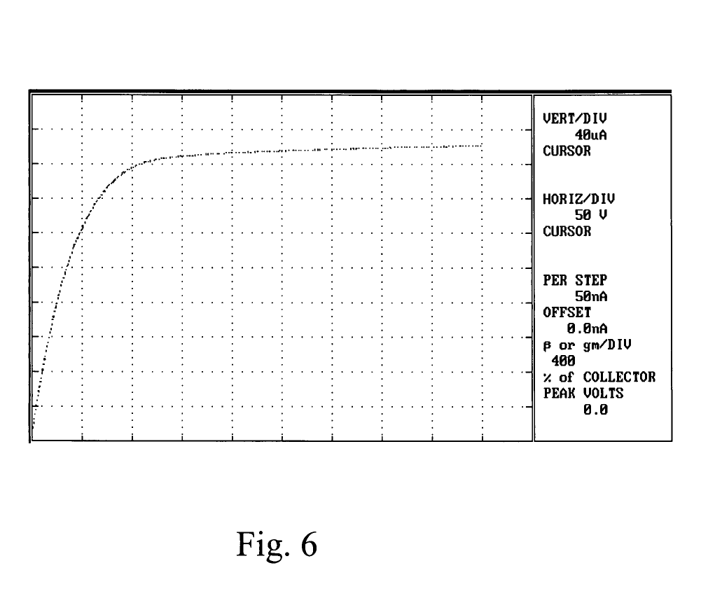

Said high-voltage resistance being shown is capable to “throttle”, considerably increasing the resistivity thereof, when the voltage at the ends exceeds a certain value, as shown in detail in the diagram of FIG. 6.

It can be noticed from this typical curve, realised by means of a curve tracer, that in the almost linear area thereof the resistance is used as feedback from the collector of the IGBT transistor TR1, in order to stabilize the system, while the feature thereof to pinch at high voltage is used when said IGBT transistor is turned off, since, when the collector voltage thereof increases, the current which can flow through the resistance cannot turn it on, as it would have happened instead with a linear-behavior component.

The solution can be obtained by using also other high-voltage technologies allowing a pinched resistance to be integrated.

On the contrary, the IGBT transistor 18 comprises a semiconductor substrate 16 of said second heavily doped conductivity type (P++), realizing the bipolar transistor conduction electrodes, a region 21 of said second heavily doped conductivity type (P+), called a body region, realized in the first epitaxial layer 19 of said first slightly doped conductivity type (N−), while the driving terminal is realized in contact with the first epitaxial layer 19 itself.

The vertical MOS transistor comprises said body region 21 wherein a source region 23 of said first heavily doped conductivity type (N+), is integrated.

A gate region 24 completes the IGBT transistor 18; a side portion of the region 21, wherein the source region 23 is integrated, can be used as body region 21b for the IGBT transistor.

The resistance 8 is connected to the collector of the transistor 18 by placing the respective substrates 9 and 16 of the two dies on the same package frame 17, while the connection to the gate 24 of the transistor 18 is performed by means of an inner connection wire 25.

Some or all of the circuitry of FIG. 10 may be disposed on one or more integrated circuits. For example, OP1, TR1, TR2, and the circuitry of block A may be disposed on the same integrated circuit. Furthermore, such one or more integrated circuits may compose a system such as the electronic system of an automobile.

Furthermore, one may replace the JFET TR2 of FIGS. 9 and 10 with other elements, such as a MOS transistor or bipolar transistor, which can be made to operate in a mode where the resistance of the element varies with the voltage across the element.

From the foregoing it will be appreciated that, although specific embodiments of the invention have been described herein for purposes of illustration, various modifications may be made without deviating from the spirit and scope of the invention.

1. A circuit for dynamic control of a power transistor in applications for high voltage and of the type wherein a power transistor has a conduction terminal connected to a load and a control terminal receiving a driving signal from a driver block activated by a trigger signal received on a circuit input terminal, wherein the circuit comprises a JFET component inserted between the conduction and control terminal of the power transistor and equal to a resistance with non-linear feature.

2. A circuit according to claim 1, wherein said JFET component is a transistor having respective drain and source terminals connected to the conduction and control terminals of said power transistor, as well as a gate terminal connected to a voltage reference.

3. A circuit according to claim 1, wherein said JFET component is monolithically integrated in the structure of said power transistor.

4. A circuit according to claim 1, wherein said JFET component is a feedback resistance for the conduction terminal of said power transistor.

5. A circuit according to claim 1, wherein said JFET component is forced to operate in a predetermined output feature in the ohmic area with a constant resistance value.

6. A circuit according to claim 2, wherein said JFET transistor is associated with a circuit adjusting the voltage drop between the gate and source terminals of the JFET transistor to keep its absolute value lower than a pinch-off voltage.

7. A circuit according to claim 6, wherein said circuit is inserted between the source terminal of the JFET transistor and the control terminal of the power transistor and it comprises a pair of current mirrors to supply the same current of said JFET transistor.

8. A circuit according to claim 6, wherein said circuit realizes a feedback connection on said conduction terminal of the power transistor being independent from the voltage value on the control terminal of the same power transistor.

9. A circuit according to claim 2, wherein said JFET component operates with a constant voltage drop Vgs.

10. A circuit for driving a load, the circuit comprising:
a switch having a first conduction node operable to drive the load and a control node operable to receive a switch-control signal; and
an element having a first node coupled to the first conduction node, a second node coupled to the control node, and, between the first and second nodes, an impedance level that varies with a voltage across the first conduction and control nodes.

11. The circuit of claim 10 wherein the switch comprises an insulated-gate bipolar transistor having a collector coupled to the conduction node, a gate coupled to the control node, and an emitter.

12. The circuit of claim 10 wherein the element comprises a transistor having a first drive node coupled to the first conduction node of the switch, a second drive node coupled to the control node of the switch, and a control node operable to receive a reference voltage.

13. The circuit of claim 10, further comprising an interface disposed between the second node of the element and the control node of the switch and operable to maintain a voltage at the second node of the element at a substantially constant level.

14. The circuit of claim 10, further comprising a current mirror having an input node coupled to the second node of the element and having an output node coupled to the control node of the switch.

15. The circuit of claim 10, further comprising:
the switch having a second conduction node; and
a feedback circuit coupled between the control and second conduction nodes of the switch and operable to cause the switch to conduct a predetermined level of current between the first and second conduction nodes.

16. The circuit of claim 10, wherein the switch and the element are disposed on a same integrated-circuit die.

17. A system, comprising:
a load;
a switch having a first conduction node coupled to the load and a control node operable to receive a switch-control signal; and
an element having a first node coupled to the first conduction node, a second node coupled to the control node, and a nonlinear profile of current between the first and second nodes versus voltage across the first and second nodes.

18. The system of claim 17 wherein the load comprises an ignition coil.

19. A method, comprising:
driving a load via a first conduction node of a switch in response to a control signal on a control node of the switch; and
feeding back to the control node a first signal that is nonlinearly related to a signal level at the first conduction node.

20. The method of claim 19 wherein feeding back comprises feeding back to the control node a current having a level that is nonlinearly related to a voltage level at the first conduction node.

21. The method of claim 19, further comprising feeding back to the control node a second signal that is linearly related to a signal level at a second conduction node of the switch.

22. The method of claim 19 wherein feeding back comprises:
generating the first signal at a first node of an element having a second node coupled to the first conduction node of the switch; and
maintaining the first node of the element at substantially a predetermined signal level.

23. The method of claim 19, further comprising feeding back to the control node a second signal that is related to a signal level at a second conduction node of the switch and that causes the switch to limit a level of current with which the switch drives the load.
